(19) United States
(12) Patent Application Publication
(10) Pub. No.: US 2026/0221213 A1
(43) Pub. Date: Jul. 30, 2026

(54) EFFICIENT MEMORY REPAIR ARCHITECTURE

(71) Applicant: Google LLC, Mountain View, CA (US)

(72) Inventors: Mayank Parasrampuria, Bangalore (IN); Rajesh Gottumukkala, Bengaluru (IN)

(21) Appl. No.: 19/159,122

(22) PCT Filed: Feb. 24, 2023
(86) PCT No.: PCT/US2023/013825

§ 371 Date: Aug. 22, 2025

(51) Int. Cl. G11C 29/44

(52) U.S. Cl. CPC G11C 29/4401

(57) ABSTRACT

A device includes a plurality of cores having a plurality of configurable self-repair pipelines, wherein each core of the plurality of cores comprises a plurality of pipeline flops for routing self-repair data to the plurality of cores in parallel, wherein a series of connected pipeline flops forms one of the plurality of configurable self-repair pipelines.

### BACKGROUND

Multiple memories and compute cores are often embedded on a computer chip, such as complex application specific integrated circuits, (ASICs) microprocessors, or systems on-a-chip. In some cases, multiple cores are embedded in an abutted architecture to save area on the chip for other components. In this specification, an abutted architecture refers to a chip design having a layout in which multiple cores are adjacent to one another without leaving space for data communication channels or other functional blocks between the cores. This means that communications between non-adjacent cores requires sending data through one or more intermediate cores between the non-adjacent cores.

Scan insertion bits (SiB) interfaces and built-in self repair (BISR) interfaces are examples of hardware components that can modify the operation of a chip post manufacture. In particular, an SiB interface can enable or disable an entire core, and a BISR interface can enable or disable particular portions of a memory that are faulty. At startup time, controllers for these interfaces configure corresponding hardware devices by providing configuration data. When working with abutted cores in a sequence, this configuration data can be concatenated. However, the abutted architecture can require daisy chaining large amounts of configuration data through a serial data path through all the abutted cores. This layout can increase the power-up time and timing complexity of the system due to greater lengths of the data paths.

### SUMMARY

This specification describes a system which can route self-repair data to multiple memories in parallel using configurable pipelines implemented by pipeline flops. This approach allows for a reduced power-up time of the system and a shorter length of self-repair paths.

Particular embodiments of the subject matter described in this specification can be implemented so as to realize one or more of the following advantages.

The systems and methods described in this specification can reduce the area required for memories and self-repair systems on a chip. For example, a channel-less abutted design significantly reduces the area required. Additionally, the systems and methods described can reduce the required power-up time due to a shorter length of self-repair paths. The systems and methods described also provide custom integration and enable multiple parallel self-repair interfaces.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A is a diagram of an example chain of cores.

FIG. 1B is a diagram of an example chain of cores containing self-repair pipelines.

FIG. 1C is a diagram of an example core containing self-repair pipelines executing a data handshake.

FIG. 2 is a diagram of data flow between cores containing self-repair pipelines.

FIG. 3 is a flowchart of a method of routing self-repair data to a memory.

Like reference numbers and designations in the various drawings indicate like elements.

### DETAILED DESCRIPTION

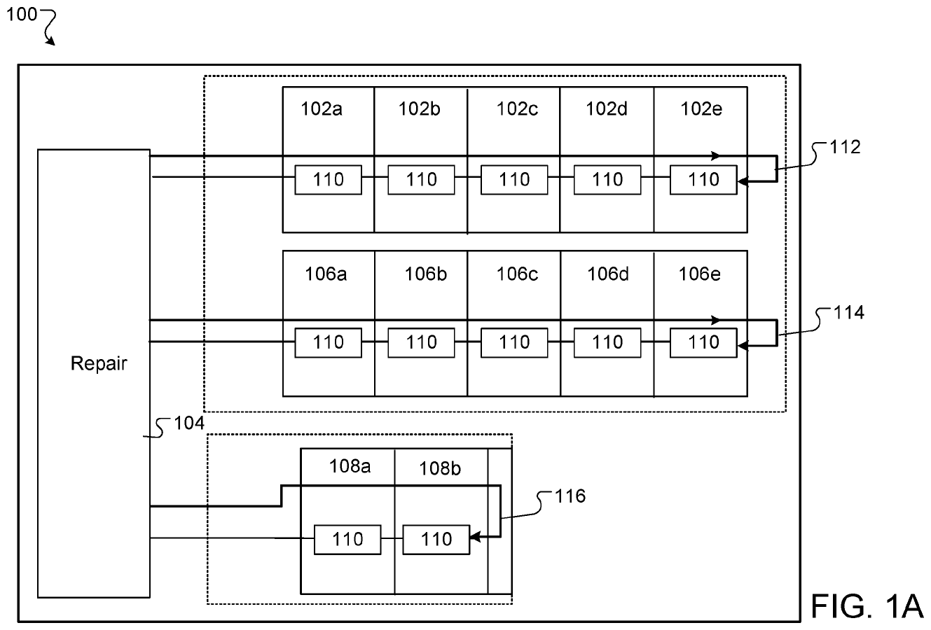

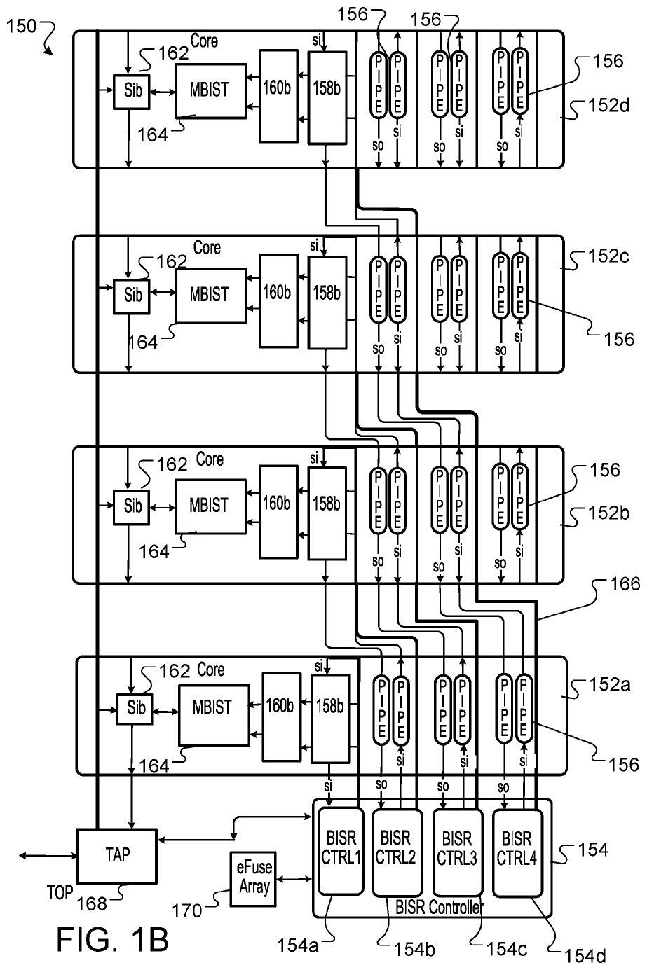

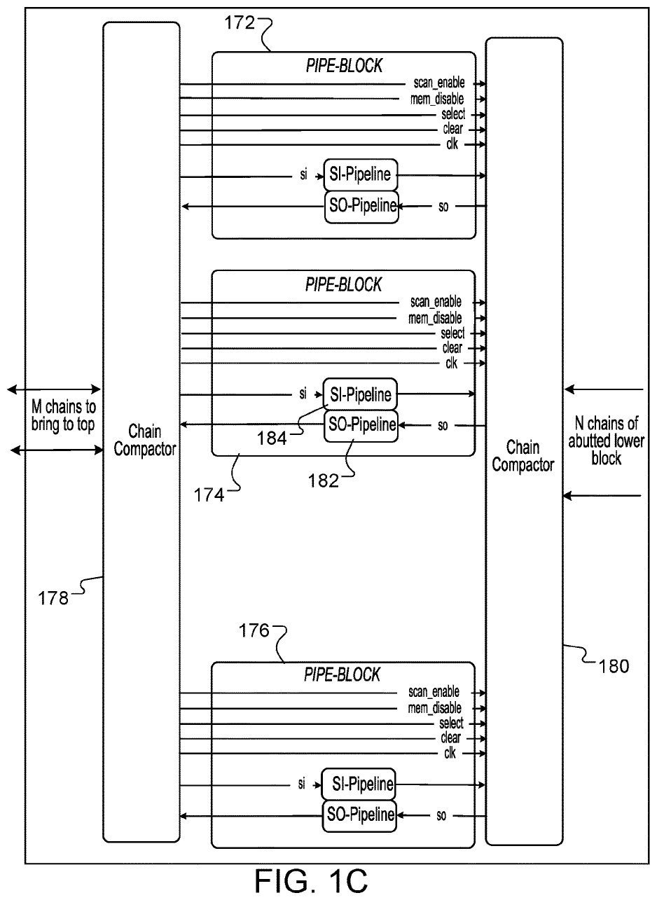

FIG. 1A is a diagram of a prior art system 100 that illustrates data flow between a first set of abutted cores 102a, 102b, 102c, 102d, 102e connected to a self-repair controller 104, e.g., a BISR controller. In this specification, a core is a modular hardware device integrated into a larger on-chip system. In many cases, similar or identical instances of cores are abutted or abutted on the chip to save silicon area and to reduce communication timing. The abutted design of the cores 102a-e means that there are no data processing channels or other processing components between the cores.

In this example, a second set of abutted cores 106a, 106b, 106c, 106d, 106e is also connected to the self-repair controller 140. And a third set of abuttedabutted cores 108a, 108b are also connected to the self-repair controller 104. Each abutted core 102a, 102b, 102c, 102d, 102e, 106a, 106b, 106c, 106d, 106e, 108a, 108b can have substantially similar or identical components to each other or to other cores in the abutted set, but can be connected to the system differently.

As shown in FIG. 1A, each set of abutted cores includes internal wires to route data from the self-repair controller 104 to the self-repair components 110. In an abutted design, in order for self-repair data to reach the last core 102e, the data must pass through all the other cores 102a, 102b, 102c, 102d through a wire 112. Having a longer wire 112 creates problems with respect to timing closure, and concatenation of the self-repair components 110 causes an increase in the power-up time of the system. The wire 112 needs to be long because it must pass through each of the cores to reach the furthest core 102e, e.g., due to the abutted configuration. The data also must pass through each self-repair component 110 in the set of abutted cores 102a, 102b, 102c, 102d, 102e to return to the self-repair controller 104. Routing the data through each self-repair component also increases the power-up time of the system.

The second set of abutted cores 106a, 106b, 106c, 106d, 106e routes data from the self-repair controller 104 to the self-repair components 110 similarly to the set of abutted cores 102a, 102b, 102c, 102d, 102e. In particular, a wire 114 passes through the other cores 106a, 106b, 106c, 106d and connects the furthest core 106e to the self-repair controller 104. Again, the timing closure becomes a challenge for 106e core due to increase in the length of the wire 114. Also, the data must pass through each self-repair component 110 in the set of abutted cores 106a, 106b, 106c, 106d, 106e to return to the self-repair controller 104, which increases the power up time of the system.

The third set of abutted cores 108a, 108b route data from the self-repair controller 104 to the self-repair components similarly to the first set of abutted cores and the second set of abutted cores. However, as illustrated, there are only two abutted cores 108a, 108b in the third set of abutted cores. A wire 116 connects the furthest core 108b to the self-repair controller 104. Again, the data must pass through each of the self-repair components 110 in the set of abutted cores 1080a, 108b to return to the self-repair controller. The wire 116 in the third set of abutted cores 108a, 108b is shorter than the wires 112 and 114 of the first and second sets of abutted cores, respectively, so the third set of abutted cores 108a, 108b will have a relaxed timing closure challenges relative to the first and second sets of abutted cores. However, the system overall will have a longer power-up time because the data traveling on the wires 112, 114, and 116 must each pass through an entire set of abutted cores.

The techniques described in this specification can reduce the power-up time of systems that use abutted cores. For example, the illustrated systems have reduced power-up times relative to the prior system 100 of FIG. 1A.

FIG. 1B is a diagram of an improved system 150 that includes multiple parallel self-repair interfaces to reduce the power-up time of the system 150. The improved system includes an example abutted set of cores 152a, 152b, 152c, 152d connected to a self-repair controller 154, which can be implemented using any appropriate self-repair protocol, e.g., a BISR controller. The self-repair controller 154 can include multiple self-repair subcontrollers 154a, 154b, 154c, 154d that effectuate the parallel self-repair configuration.

The example cores 152a, 152b, 152c, 152d have an abutted layout, which can reduce the area of the system 150, but which requires sending data through some cores.

Each abutted core 152a, 152b, 152c, 152d includes a same number of pipeline flops and a respective self-repair component 158a, 158b, 158c, 158d. Each self-repair component 158a-d is a hardware module or microcontroller that configures each respective memory 160a-d with self-repair data.

Pipeline flops are circuits, e.g., latches or flip-flops, that can store and propagate data, e.g., to receive input data and pass the input data along as output on the next clock cycle. The pipeline flops can be used as data propagation elements, e.g., to pass data along in a sequential logic circuit. The pipeline flops of the abutted cores can be coupled together to allow for parallel configuration of self-repair data by the self-repair controller 154. When a number of pipeline flops are coupled to one another in a sequence, they can be referred to as a pipeline. The arrangement of the pipeline flops within the abutted cores 152a-d allows for multiple parallel pipelines to be used for self-repair data.

In this example, each abutted core 152a-d includes three outgoing pipeline flops and three incoming pipeline flops. This design allows for the four abutted cores 152a-d to be configured in parallel. The first abutted core 152a includes outgoing pipeline flops 131a, 132a, and 133a. The second abutted core 152b includes outgoing pipeline flops 131b, 132b, and 133b. The third abutted core 152c includes outgoing pipeline flops 131c, 132c, and 133c. And the fourth abutted core 152d includes outgoing pipeline flops 131d, 132d, and 133d. Each abutted core 152a-d also includes three incoming pipeline flops for sending data in the other direction back to the self-repair controllers 154a-d.

The pipeline flops can be configured to execute a data handshake, in which the pipeline flops transmit and receive data in one execution cycle. Data handshakes are further discussed with reference to FIG. 1C below. In some implementations, each pipeline implemented by coupled pipeline flops can be connected to a respective self-repair controller 154a, 154b, 154c, 154d and can route self-repair data from the respective self-repair controller to the respective self-repair component 158a, 158b, 158c, 158d, each of which can control the configuration of a memory 160a, 160b, 160c, 160d, e.g., by configuring the memory with self-repair data that can, for example, disable one or more faulty rows or portions of each memory. Corresponding pipelines in the reverse direction can route data from the respective self-repair components 158a, 158b, 158c, 158d to the respective self-repair controllers 154a, 154b, 154c, 154d, e.g., through a data handshake. For example, feedback data can be routed from the self-repair components to the self-repair controllers.

Self-repair data can include data which addresses flaws in manufacturing process or other sources of damage to memory devices, e.g., portions of the memory that are faulty. The self-repair data can for example specify which addresses, segments, rows, or columns to use within the memory, and, implicitly or explicitly, which to disable. Avoiding portions of the memory that are faulty, e.g., due to manufacturing errors, can reduce errors associated with failing memory. Generally, self-repair data is routed to the memories during power-up of the system, and thus reducing the required time to route the self-repair data from the self-repair controller to the self-repair components reduces the power-up time of the system.

The design of the abutted cores 152a-d allows the self-repair subcontrollers 154a-d to configure the self-repair components 158a-d through parallel pipelines. To do so, the data can be transmitted through pipeline flops forming parallel pipelines between the self-repair controller 154 and each abutted core.

In this example, the first self-repair subcontroller 154a can send self-repair data directly to the self-repair component 158a of the first abutted core 152a. In other words, the first self-repair subcontroller 154a need not use a pipeline and can instead be directly electrical coupled to an interface on the abutted core 152a that connects to the first self-repair component 158a. The second self-repair subcontroller 154b can send self-repair data through a first pipeline flop 131a within the first abutted core 152a and on to an interface of the second abutted core 152b that connects to the second self-repair component 158b.

The third self-repair subcontroller 154c can send self-repair data through a pipeline that includes a second pipeline flop 132a of the first abutted core 152a and a first pipeline flop 131b of the second abutted core 152b and on to an interface of the third abutted core 152c that connects to the third self-repair component 158c.

The fourth self-repair subcontroller 154d can send self-repair data through another pipeline that includes a third pipeline flop 133a of the first abutted core 152a, a second pipeline flop 132b of the second abutted core 152b, and a first pipeline flop 131c of the third abutted core 152c and on to an interface of the fourth abutted core 152d that connects to the fourth self-repair component 158d.

As shown in FIG. 1, the pipeline flops 131a, 132a, and 133a of the first abutted core 152a implement three parallel pipelines: 1) 131a; 2) 132a, 131b; and 3) 133a, 132b, and 131c. Meanwhile, the pipeline flops 131b and 132b of the second abutted core 152b implement two parallel pipelines, and the pipeline flop 131c of the third abutted core 152c implements one pipeline. Each abutted core 152a-d includes one fewer pipeline flop than the number of abutted cores in the system 150. In the illustrated example, there are four abutted cores 152a, 152b, 152c, 152d, and each core contains three pipeline flops in each direction.

Thus, although several pipeline flops are not used at all, e.g., the pipeline flops 131d, 132d, and 133d, this design is still advantageous for a number of reasons. First, this design allows all the abutted cores to have the same design, which simplifies the manufacturing process. Second, this design implements parallel self-repair pipelines, which improves the startup time of the system.

In implementations with more or fewer cores, the number of pipeline flops in each core, and in each direction, can be increased or decreased as needed. The pipelines can be configured to route the self-repair data in parallel, i.e., simultaneously. Routing the self-repair data in parallel can reduce the power-up time of the system, e.g., how long the system takes to be available for use after powering up. Routing the self-repair data in parallel significantly reduces the power-up time, e.g., in comparison to the system 100 of FIG. 1A. Also, because the pipelines execute data handshakes and pass both inputs and outputs through the self-repair pipelines, data can return to the self-repair controller 154 significantly faster. This also reduces the power-up time, e.g., in comparison to the system 100 of FIG. 1A. The pipelines can also be configured to route inputs and outputs to the same respective self-repair controller. For example, the pipeline implemented by the pipeline flops 133a, 132b, and 131c routes self-repair data using a diagonal integration scheme to reach the self-repair component 158d, and routes output data in similar manner through incoming pipeline flops to return to the self-repair controller 154d. This reduces the power-up time of the system, by reducing the length of the chain, and the longest wire length is also reduced through which the data travels. The diagonal integration scheme refers to connecting the nth pipeline to (n-1)th of the next core and the Oth pipeline connected to the repair chain of the next core. This allows for having a consistent guideline for integration on any number of cores which are abutted. In some implementations, clock data can be synchronized to reduce timing issues.

Each core can also include a scan insertion bit (SiB) 162 that is a component which is configurable to enable or disable each core. Each core includes a Memory Built in Self-Test (MBIST) 164, which can be used to test a memory, e.g., by performing sequences of reads and writes to the memory according to a test algorithm and determining that the memory is working properly. A test access port (TAP) 168 can use test clock signals to synchronize state machine operations. A non-volatile memory (NVM) 170 permits data to be written to the memory once. After the memory is programmed, it will retain the stored values upon loss of power.

FIG. 1C illustrates pipeline flops 172, 174, 176 connected to chain compactors 178, 180. The design of the pipeline flops 172, 174, 176 and the chain compactors 178, 180 can be created based on user requirements, e.g., the desired number of cores, desired number of self-repair controllers, desired number of pipeline flops, etc. For example, the number of pipeline flops can be one fewer than the number of cores in the system, as described above. The chain compactor 178 receives a number chains (M) of logic from, e.g., a self-repair controller, a previous core, etc. and sends the same number chains (M) of logic back to, e.g., the self-repair controller, the previous core, etc. The chain compactor 180 receives a number chains (N) from, e.g., a core that is further from the self-repair controller. The chain compactor 180 also sends the same number chains (N) to the core that is further from the self-repair controller. If the number of chains received from the previous core (M) is equal to the number of chains sent to the further core (N), then the chain compactors 178, 180 can simply feed the logic through the pipeline flops 172, 174, 176 without compacting logic. If the number of chains received from the previous core (M) is lower than the number of chains sent to the further core (N), then multiple chains of downstream logic will be merged by chain compactor 178. For example, the chain compactor 178 can merge chains based on user input by concatenating them. In some implementations, multiple signals which control the repair chain operations, e.g., a shift enable signal, a reset signal, a clock signal, etc. can be broadcast through the pipeline blocks 172, 174, 176. In some implementations, merging chains can include concatenating the SO-pipeline 182 with the SI-pipeline 184. If the number of chains received from the previous core (M) is greater than the number of chains sent to the further core(N) then multiple chains of downstream logic will be merged by the chain compactor 180. Feeding the data through both an SO-pipeline 182 and an SI-pipeline 184 allows the pipeline flops 172, 174, 178 to execute a data handshake, wherein the flops 172, 174, 176 transmit and receive data in one execution. Additionally, merging chains with the chain compactors 178, 180 allows different numbers of pipelines to be configured between cores.

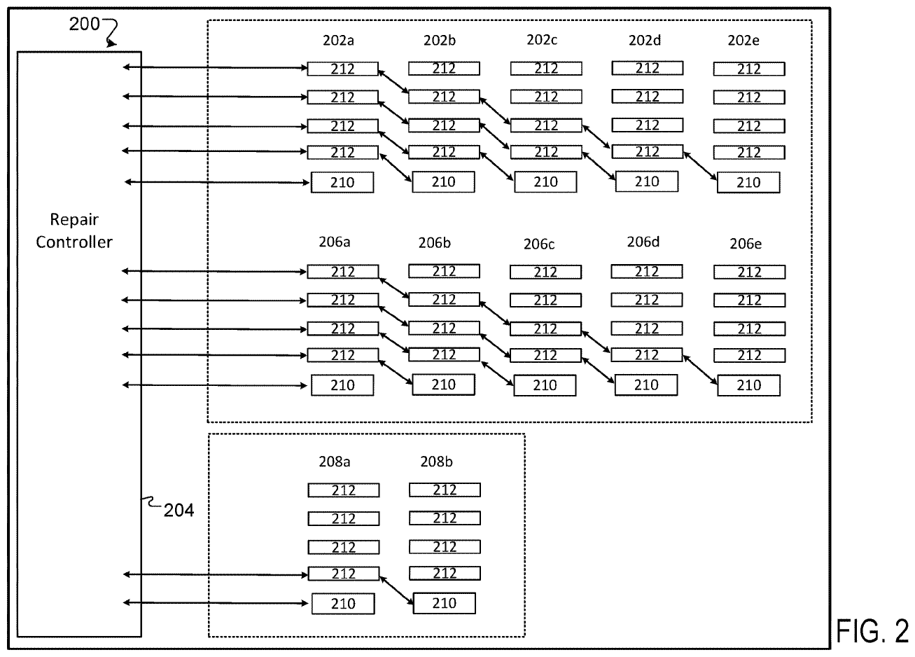

FIG. 2 is a diagram of a system 200 that illustrates data flow between a first set of abutted cores 202a, 202b, 202c, 202d, 202e connected to a self-repair controller 204, e.g., a BISR controller. A second set of abutted cores 206a, 206b, 206c, 206d, 206e is also connected to the self-repair controller. A third set of abutted cores 208a, 208b is connected to the self-repair controller. Each core 202a, 202b, 202c, 202d, 202e, 206a, 206b, 206c, 206d, 206e, 208a, 208b can be identical, but connected to the system differently. An advantage of all of the cores being identical is that they can be reconfigured as desired in different systems. Each set of abutted cores contains pipelines to route data from the self-repair controller 204 to a respective self-repair component 210. The pipeline flops 212 route the self-repair data diagonally when data flows through the abutted cores. As described above, each core can have one fewer pipeline flop than the number of cores in the set of abutted cores. For example, the first set of abutted cores 202a, 202b, 202c, 202d, 202e has five abutted cores, but only four pipeline flops 212. In the first set of abutted cores, the closest core 202a has its self-repair component 210 connected to the self-repair controller 204. The next closest core 202b has its self-repair component 210 connected to the first pipeline flop 212 of the core 202a, which is connected to the self-repair controller 204. The next closest core 202c has its self-repair component 210 connected to the first pipeline flop 212 of the core 202b, which is connected to the second pipeline flop 212 of the core 202a, which is connected to the self-repair controller 204. The penultimate core 202d has its self-repair component connected to the first pipeline flop 212 of the core 202c, which is connected to the second pipeline flop of the core 202b, which is connected to the third pipeline flop of the core 202a, which is connected to the self-repair controller 204. The furthest core 202e has its self-repair component connected to the first pipeline flop 212 of the core 202d, which is connected to the second pipeline flop of the core 202c, which is connected to the third pipeline flop of the core 202b, which is connected to the fourth pipeline flop of the core 202a, which is connected to the self-repair controller 204. Data can flow through the set of cores from the self-repair controller 204 to each self-repair component in parallel because each self-repair component is connected to the self-repair controller 204 through a respective pipeline. Also, data can flow in the opposite direction from the self-repair components to the self-repair controller. For example, feedback data can be routed from the self-repair components to the self-repair controllers. In some implementations, each pipeline flop can be configured to execute a data handshake. This is advantageous to wiring each self-repair component in series because it reduces the length of the self-repair paths relative to self-repair components wired in series. Reducing the length of the self-repair paths reduces the loading time and power-up time of the components.

The second set of abutted cores 206a, 206b, 206c, 206d, 206e routes data from the self-repair controller 204 to the self-repair components 210 similarly to the set of abutted cores 202a, 202b, 202c, 202d, 202e. More or fewer abutted cores can be used in different implementations. For example, more abutted cores could be used if each core contained additional pipeline flops.

The third set of abutted cores 208a, 208b route data from the self-repair controller 204 to the self-repair components similarly to the set of abutted cores and the second set of abutted cores. However, as illustrated, there are only two abutted cores 208a, 208b in the third set of abutted cores. The third set of abutted cores 208a, 208b illustrates that fewer cores can be used, even with a greater number of pipeline flops in each core.

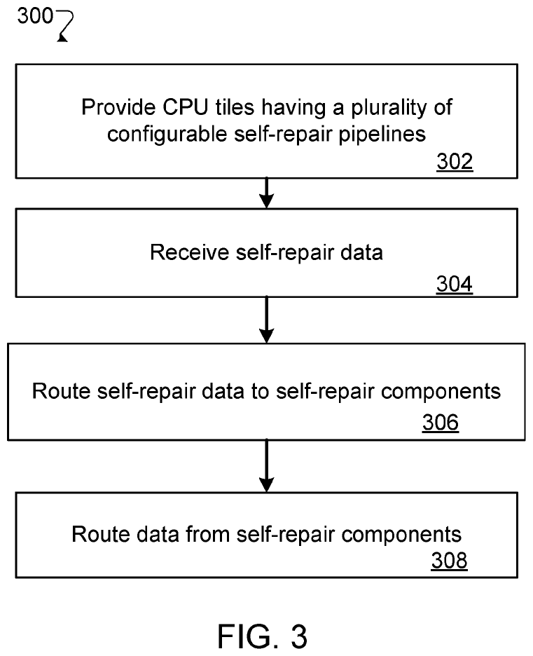

FIG. 3 is a flowchart of an example process 300 for routing self-repair data to a memory. The example process can be performed by one or more components of a system. The example process will be described as being performed by, e.g., the cores 102a, 102b, 102c, 102d of FIG. 1, configured accordingly in accordance with this specification.

The cores provide a plurality of configurable self-repair pipelines (302). For example, the cores can be similar to the cores 102a, 102b, 102c, 102d of FIG. 1.

Each of the cores can include a plurality of pipeline flops for routing self-repair data to the plurality of cores in parallel. Each core includes a number of pipeline flops that is greater than or equal to one fewer than the number of cores. For example, if there are four cores, each core includes at least three pipeline flops. If there are five cores, each core includes at least four pipeline flops.

The cores receive self-repair data (304). For example, the cores can receive self-repair data from a self-repair controller, e.g., a BISR controller, as described in FIG. 1.

The cores route self-repair data to self-repair components within the cores (306). The cores can route the self-repair data to self-repair components in parallel, as described above. Also, the cores can route the self-repair data diagonally through the self-repair pipelines. For example, the cores can route self-repair data as described in FIG. 2.

The cores route data from the self-repair components (308). For example, data can be routed from the self-repair components to a self-repair controller, e.g., through a data handshake. Data can be routed from the self-repair components to multiple self-repair controllers, as described with respect to FIG. 1. For example, feedback data can be routed from the self-repair components to the self-repair controllers.

Embodiments of the subject matter and the functional operations described in this specification can be implemented in digital electronic circuitry in computer hardware, including the structures disclosed in this specification and their structural equivalents, or in combinations of one or more of them. The processes and logic flows can also be performed by special purpose logic circuitry, e.g., an FPGA or an ASIC, or by a combination of special purpose logic circuitry and one or more programmed computers.

In addition to the embodiments described above, the following embodiments are also innovative:

Embodiment 1 is a device comprising a plurality of cores, each core comprising:
a memory device; and
a plurality of pipeline flops,
wherein different sequences of pipeline flops in different respective cores are configured to implement a plurality of parallel self-repair pipelines for routing self-repair data to each respective memory device of the plurality of cores.

Embodiment 2 is the device of embodiment 1, wherein the plurality of cores have an abutted architecture.

Embodiment 3 is the device of any one of embodiments 1-2, further comprising:
a self-repair controller configured to generate signals for sending self-repair data to each memory device within the plurality of cores.

Embodiment 4 is the device of embodiment 3, wherein both inputs and outputs between the self-repair controller and the plurality of cores are passed through the self-repair pipelines.

Embodiment 5 is the device of any one of embodiments 1-4, wherein a number of pipeline flops in each core is one less than a number of cores on the device.

Embodiment 6 is the device of any one of embodiments 1-5, wherein each pipeline flop in each self-repair pipeline is coupled to a pipeline flop in an adjacent core or a self-repair component in an adjacent core.

Embodiment 7 is the device of embodiment 6, wherein each self-repair pipeline of a core is diagonally integrated with an adjacent core.

Embodiment 8 is the device of any one of embodiments 1-7, further comprising multiple self-repair subcontrollers, each self-repair subcontroller configured to send self-repair data on a respective parallel self-repair pipeline.

Embodiment 9 is a method performed by device comprising a plurality of cores, each core comprising:
a memory device; and
a plurality of pipeline flops,
the method comprising routing self-repair data to each respective memory device of the plurality of cores in parallel using different sequences of pipeline flops in different respective cores that implement a plurality of parallel self-repair pipelines.

Embodiment 10 is the method of embodiment 9, wherein the plurality of cores have an abutted architecture.

Embodiment 11 is the method of any one of embodiments 9-10, wherein the device comprises a self-repair controller that is configured to generate signals for sending self-repair data to each memory device within the plurality of cores.

Embodiment 12 is the method of embodiment 11, wherein both inputs and outputs between the self-repair controller and the plurality of cores are passed through the self-repair pipelines.

Embodiment 13 is the method of any one of embodiments 9-12, wherein a number of pipeline flops in each core is one less than a number of cores on the device.

Embodiment 14 is the method of any one of embodiments 9-13, wherein each pipeline flop in each self-repair pipeline is coupled to a pipeline flop in an adjacent core or a self-repair component in an adjacent core.

Embodiment 15 is the method of embodiment 14, wherein each self-repair pipeline of a core is diagonally integrated with an adjacent core.

Embodiment 16 is the method of any one of embodiments 9-15, wherein the device comprises multiple self-repair subcontrollers, each self-repair subcontroller configured to send self-repair data on a respective parallel self-repair pipeline.

While this specification contains many specific implementation details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain some cases, multitasking and parallel processing may be advantageous.

What is claimed is:

1. A device comprising a plurality of cores, each core comprising:
a memory device; and
a plurality of pipeline flops,
wherein different sequences of pipeline flops in different respective cores are configured to implement a plurality of parallel self-repair pipelines for routing self-repair data to each respective memory device of the plurality of cores.

2. The device of claim 1, wherein the plurality of cores have an abutted architecture.

3. The device of claim 1, further comprising:
a self-repair controller configured to generate signals for sending self-repair data to each memory device within the plurality of cores.

4. The device of claim 3, wherein both inputs and outputs between the self-repair controller and the plurality of cores are passed through the self-repair pipelines.

5. The device of claim 1, wherein a number of pipeline flops in each core is one less than a number of cores on the device.

6. The device of claim 1, wherein each pipeline flop in each self-repair pipeline is coupled to a pipeline flop in an adjacent core or a self-repair component in an adjacent core.

7. The device of claim 6, wherein each self-repair pipeline of a core is diagonally integrated with an adjacent core.

8. The device of claim 1, further comprising multiple self-repair subcontrollers, each self-repair subcontroller configured to send self-repair data on a respective parallel self-repair pipeline.

9. A method performed by device comprising a plurality of cores, each core comprising:
a memory device; and
a plurality of pipeline flops,
the method comprising routing self-repair data to each respective memory device of the plurality of cores in parallel using different sequences of pipeline flops in different respective cores that implement a plurality of parallel self-repair pipelines.

10. The method of claim 9, wherein the plurality of cores have an abutted architecture.

11. The method of claim 9, wherein the device comprises a self-repair controller that is configured to generate signals for sending self-repair data to each memory device within the plurality of cores.

12. The method of claim 11, wherein both inputs and outputs between the self-repair controller and the plurality of cores are passed through the self-repair pipelines.

13. The method of claim 9, wherein a number of pipeline flops in each core is one less than a number of cores on the device.

14. The method of claim 9, wherein each pipeline flop in each self-repair pipeline is coupled to a pipeline flop in an adjacent core or a self-repair component in an adjacent core.

15. The method of claim 14, wherein each self-repair pipeline of a core is diagonally integrated with an adjacent core.

16. The method of claim 9, wherein the device comprises multiple self-repair subcontrollers, each self-repair subcontroller configured to send self-repair data on a respective parallel self-repair pipeline.
